(19) United States
(12) Patent Application Publication
(10) Pub. No.: US 2011/0156184 A1
(43) Pub. Date: Jun. 30, 2011

(54) Methods for improving detector response and system thereof

(75) Inventors: Zoran Ninkov, Rochester, NY (US); Ross Robinson, Rochester, NY (US)

(73) Assignee: Rochester Institute of Technology, Rochester, NY (US)

(21) Appl. No.: 12/655,350

(22) Filed: Dec. 29, 2009

(51) Int. Cl. H01L 31/0232; H01L 31/18; H01L 31/0216

(52) U.S. Cl. 257/432; 438/63; 257/436; 977/774; 438/69; 257/E31.003; 257/E31.119; 257/E31.127

(57) ABSTRACT

A method and system for detecting light in accordance with other embodiments of the present invention includes providing at least one imaging sensor that detects a band of wavelengths. At least one layer of undoped quantum dots is optically coupled to the at least one imaging sensor. The at least one layer of undoped quantum dots absorbs at one or more wavelengths outside the band of wavelengths and outputs at least partially in the band of wavelengths.

### FIELD OF THE INVENTION

The present invention relates to methods and systems for improving detector response and, more particularly, to methods for improving detector response with undoped quantum dots and systems thereof.

### BACKGROUND

Silicon based imaging sensors have very poor quantum efficiency with wavelengths of light below about 400 nm. This very poor quantum efficiency results from absorption of the light by the gates, oxide and encapsulation in the silicon based imaging sensor. As a result of this absorption, little, if any, of the light is able to reach the active portion of these silicon based imaging sensors.

One prior technique to increase the quantum efficiency light with a wavelength below about 400 nm is to polish the back side of the imaging sensing wafer until the active layer is nearly exposed and then to illuminate the back side. Although this technique improves quantum efficiency it is an expensive, time consuming, and delicate process.

Another technique to increase the quantum efficiency light with a wavelength below about 400 nm is to use a material which will emit visible light when exposed to ultraviolet light. Historically, a florescent dye has been used to convert ultraviolet and higher energy photons to visible light. Again although this technique improves quantum efficiency it has several disadvantages. For example, one of the disadvantages is that the florescent dye coating degrades with time, ultraviolet exposure, and vacuum exposure. Another disadvantage is that users of these imaging sensors with the florescent dye coating have reported uniformity problems.

### SUMMARY

A detection system in accordance with other embodiments of the present invention includes at least one imaging sensor that detects a band of wavelengths and at least one layer of undoped quantum dots. The layer of undoped quantum dots is optically coupled to the at least one imaging sensor. The one layer of undoped quantum dots absorbs at one or more wavelengths outside the band of wavelengths and outputs at least one emission wavelength in the band of wavelengths.

A method for detecting light in accordance with other embodiments of the present invention includes providing at least one imaging sensor that detects a band of wavelengths. At least one layer of undoped quantum dots is optically coupled to the at least one imaging sensor. The at least one layer of undoped quantum dots absorbs at one or more wavelengths outside the band of wavelengths and outputs at least one emission wavelength in the first band of wavelengths.

The present invention provides more effective and efficient methods and systems for detecting a broader spectrum of light or other radiation. With the present invention, signal levels which previously would have been detected as noise are increased by several orders of magnitude so that they can now be detected.

Additionally, the present invention is optically coupled to as opposed to being incorporated in or electrically coupled to the imaging sensor or other detector making the present invention substantially easier and less expensive to produce. The present invention also utilizes undoped quantum dots which are easier and less expensive to manufacture.

Further, the present invention is substantially more robust and will not suffer the degradation issues which have plagued prior detectors. Even further, by utilizing the layer of undoped quantum dots the present invention is able to provide a more rapid imaging response than previously could be achieved with prior art imaging sensors or other detectors.

### BRIEF DESCRIPTION OF THE DRAWINGS

FIG. 1 is a cross-sectional view of a detection system with a layer of undoped quantum dots on and optically coupled to an imaging sensor in accordance with embodiments of the present invention;

FIG. 2 is a cross-sectional view of another detection system with a layer of undoped quantum dots on a window which is optically coupled to an imaging sensor in accordance with other embodiments of the present invention;

FIG. 3 is a cross-sectional view of another detection system with a layer undoped quantum dots which is optically coupled by a lens system to an imaging sensor in accordance with other embodiments of the present invention;

FIG. 4 is a cross-sectional view of another detection system with a layer of undoped quantum dots which is optically coupled by a fiber optic bundle to an imaging sensor in accordance with other embodiments of the present invention; and

FIG. 5 is a chart illustrating different emission wavelengths based on different sizes of undoped quantum dots.

### DETAILED DESCRIPTION

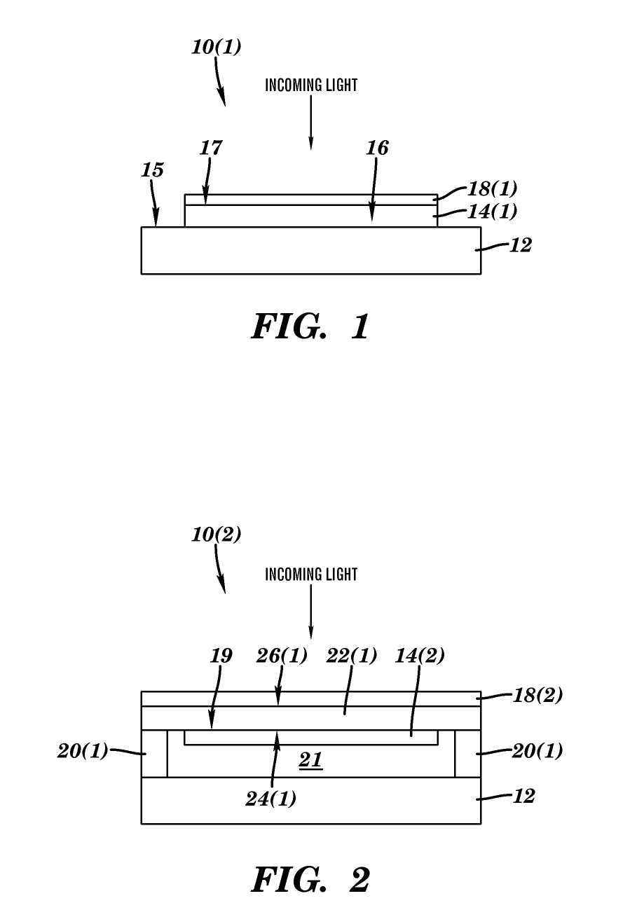

A detection system 10(1) in accordance with embodiments of the present invention in accordance with embodiments of the present invention is illustrated in FIG. 1. The detection system 10(1) includes an imaging sensor 12 and a layer of undoped quantum dots 14(1), although the detection system 10(1) can include other types and numbers of elements connected in other manners. The present invention provides more effective and efficient methods and systems for detecting a broader spectrum of light or other radiation.

Referring to FIG. 1, the imaging sensor 12 in the detection system 10(1) is a charge coupled device, although other types and numbers of imaging sensors or other detectors in other arrangements can be used. The imaging sensor 12 detects a first band of wavelengths, such as an infrared through a visible spectrum, i.e. above about 400 nm, but in this example can not effectively detect ultraviolet, i.e. below about 400 nm, although the imaging sensor or other detector can be designed to detect other bands or ranges of wavelengths. In an alternative embodiment, the imaging sensor can detect between about 1 micron and 5 micron, but can not effectively detect below about 1 micron, although other imaging sensors could have other detection ranges.

A surface 15 of the imaging sensor 12 is adjusted to change surface tension and wetting characteristics prior to the application of the layer of undoped quantum dots 14(1) to improve uniformity, although other types and numbers of adjustments to the surface of the imaging sensor 12 can be used or the surface can be left unaltered. By way of example only, a process to modify a SiO₂ surface is disclosed in an article entitled, “100-nm Quantum Dot Waveguides By Two-Layer Self-Assembly” in: Lasers and Electro-Optics Society, 2005. LEOS 2005. The 18th Annual Meeting of the IEEE, published Oct. 22-28, 2005, pp. 194-195 which is herein incorporated by reference.

The layer of undoped quantum dots 14(1) is located on the surface 15 of the imaging sensor 12, although the layer of undoped quantum dots can be optically coupled to the imaging sensor 12 in other manners with other locations and elements, such as on a window near the imaging sensor, adjacent a lens, or at the end of a fiber optic bundle by way of example only. In this particular example, the layer of undoped quantum dots 14(1) also has a substantially uniform thickness at least over a target detection area, although the layer could have other thickness configurations. A variation in the thickness of the layer of undoped quantum dots 14(1) could result in undesirable variations of quantum efficiency. Additionally, the layer of undoped quantum dots 14(1) has a thickness which is sufficient to absorb the majority of the light of interest without being too thick to reabsorb the emission wavelengths from the layer of undoped quantum dots 14(1).

For light from a higher energy band to be converted to detectable light and contribute to the quantum efficiency it must first be absorbed by the layer of undoped quantum dots 14(1). One model for the proportion of light absorbed by the layer of undoped quantum dots 14(1) is provided with the Beer-Lambert law (1) as explained in greater detail below.

I_d=I_{—}0e^{-CNd} (1)

I_{—}0=Initial intensity

I_d=Intensity at depth d

N=Number density of Quantum Dots in film

C=optical cross section of an individual quantum dot

d=depth into film

P=Packing density

Vd=volume of individual QD

a=radius of individual QD

The number density (N) is the packing density divided by the volume of an individual dot. Substituting this into equation (1) results in equation (3) below:

$$\begin{matrix}N = \frac{P}{Vd} & ( 2 ) \\ I\_d = I\_ 0 {e}^{- \frac{CPd}{Vd}} & ( 3 )\end{matrix}$$

The sum of absorption (A) and transmittance (T) is 1. Solving for the absorption gives:

A=1−T (4)

Transmittance (T) is intensity at depth d (I_d) divided by the initial intensity:

$$T = \frac{I\_d}{I\_ 0} \qquad ( 5 )$$

Apply the equation (5) definition of the fractional transmission of a film to equation (3) results in:

$$T = {e}^{- \frac{CPd}{Vd}} \qquad ( 6 )$$

Then apply the relationship between absorption and transmission given in equation (4) to equation (6) resulting in:

$$A = 1 - {e}^{- \frac{CPd}{Vd}} \qquad ( 7 )$$

This is the absorption of the incident light as a function of depth d into the layer or film of quantum dots. The layer or film depth required for a given desired absorption can be determined by solving for d in equation (7):

$$d = \frac{ln ( - A + 1 ) Vd}{CP} \qquad ( 8 )$$

By supplying information about functional form of the optical across section of an individual quantum dot, volume of an individual quantum dot and the limits on packing density the limits on functional films can be shown.

Arbitrarily thicker films with the same predicted absorbencies can be made by including an additional inert substance into the film such as a binder to space the undoped quantum dots apart. The addition of an inert spacing material will decrease the packing efficiency (P).

The volume occupied by a quantum dot of radius (a) is given by the standard volume of a sphere:

$$Vd = \frac{4}{3} π {a}^{3} \qquad ( 9 )$$

The paper entitled, “On the Absorption Cross Section of CdSe Nanocrystal Quantum Dots” by C. A. Leatherdale, W.-K. Woo, F. V. Mikulec, and, M. G. Bawendi, The Journal of Physical Chemistry B 2002 106 (31), 7619-7622, which is herein incorporated by reference in its entirety, finds that when the energy of the incident light is far above a energy of the band edge transition that the absorption cross section (C) can be approximated by a material dependent constant (a) times the radius of the QD cubed (a³). The value reported for C for 350 nm incident light is (5.501*10⁵)*a³ [cm⁻¹].

C=αa³ (10)

Substituting equations (9) and (10) into equation (8) gives equation (11) which is independent of the quantum dot size used.

$$d = - \frac{4}{3} \frac{ln ( - A + 1 ) π}{α P} \qquad ( 11 )$$

To find the film thickness for a desired application the size and absorption cross section of the QD which compose the film need to be measured. The desired value of A is set to be the desired absorption of the incoming light. Usually A will be approximately 0.99 or larger. However, A is constrained to be less then one.

The paper “A phase diagram for jammed matter”, by C. Song, W. Ping, and H. A. Makse, Nature 2008, 453, 629-632, which is herein incorporated by reference in its entirety, describes the limits on how high of a packing density can be achieved. The densest packing possible is cubic close packing with P>0.074. The densest random packing possible is P<0.634 and for a loose random packing without significant voids P<0.55. The packing density for a given film will be determined by the deposition method used to form it. For most methods values less then 0.55 are relevant.

As an example, the value for a reported by Leatherdale et al. for 350 nm incoming light and the maximum packing efficiency for loose random packing from Song et al. of P=0.55 when applied in equation (11) results in a minim film thickness of 64 nm to absorb 99% of the incoming 350 nm light.

In this example, the undoped quantum dots in layer 14(1) are undoped colloidal quantum dots which comprise individual nanocrystals, although other types of quantum dots can be used, such as undoped epitaxial quantum dots which are embedded in and are a contagious part of a host crystal lattice or core-shell quantum dots which are more robust to environmental degradation and exhibit higher efficiencies. Core-shell quantum dots are discussed in an article entitled, “(CdSe)ZnS Core-Shell Quantum Dots: Synthesis and Characterization of a Size Series of Highly Luminescent Nanocrystallites,” J. Phys. Chem. B, 1997, 101, pp 9463-9475 which is herein incorporated by reference in its entirety. Additionally, the undoped quantum dots in layer 14(1) are encased in a protective shell of material which protects these undoped quantum dots from degrading over time or from environmental influences making this detection system 10(1) more robust than prior detection systems, although the protective shell is optional.

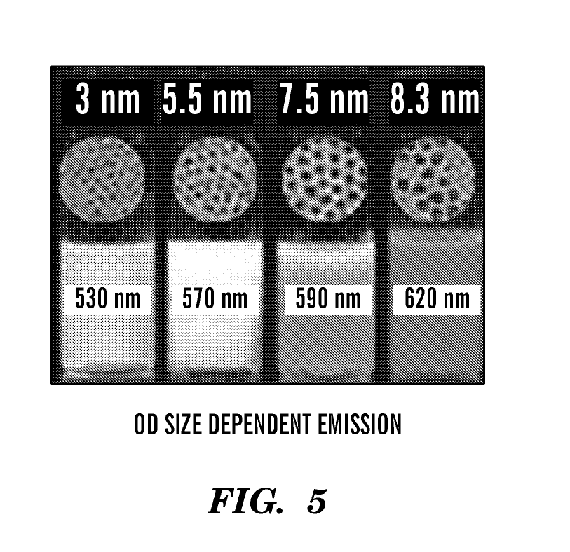

The undoped quantum dots in layer 14(1) absorb light or other radiation at a wavelength shorter then an emission wavelength of the undoped quantum dots in layer 14(1) and convert the absorbed light to an emission wavelength which is more suitable for detection by imaging sensor 12. The particular size of the undoped quantum dots in the layer 14(1) determines the emission wavelength. By way of example only, a chart illustrating different emission wavelengths based on different sizes of undoped quantum dots is illustrated in FIG. 5. In this exemplary chart, a 3.0 nm quantum dot has an emission wavelength of about 530 nm, a 5.5 nm quantum dot has an emission wavelength of about 570 nm, a 7.5 nm quantum dot has an emission wavelength of about 590 nm, and an 8.3 nm quantum dot has an emission wavelength of about 620 nm. By choosing the proper size of the undoped quantum dots in the layer 14(1) the emission can be selected to be at a wavelength that improves the quantum efficiency of the detection system 10(1). Additionally, by way of example, the undoped quantum dots could absorb at below about 400 nm and output at above about 400 nm. In another example, the undoped quantum dots could absorb at below about 1 micron and output at above about 1 micron for an image sensor with InSb detectors sensitive between about 1 micron and 5 microns.

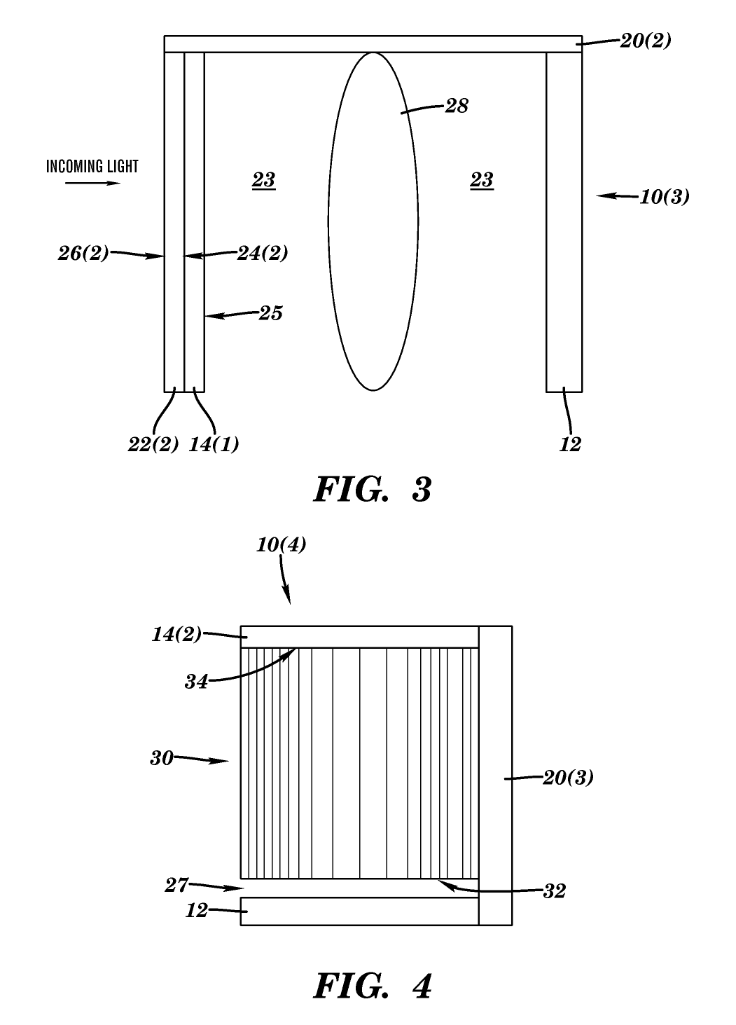

The layer 14(1) substantially contains one size of undoped quantum dots, although more then one size of undoped quantum dots size can be used. When more than one size of undoped quantum dots are used, the undoped quantum dots with the longer emission wavelength are placed adjacent a side of the layer 14(1) which faces towards the initial light source being detected, although the undoped quantum dots of different sizes can be arranged in the layer 14(1) in other manners and at other locations. For example, if more than one size of undoped quantum dots is used in the examples illustrated in FIGS. 1, 2, and 4, then the undoped quantum dots with the longer emission wavelength are placed adjacent a side of the layer 14(1) which faces towards the initial light source being detected. However, by way of example only, if more than one size of undoped quantum dots is used in the example illustrated in FIG. 3, then the undoped quantum dots with the longer emission wavelength are placed adjacent a side of the layer 14(1) which faces away from the initial light source being detected.

A binder 16 is included with the layer of undoped quantum dots 14(1), although the inclusion of a binder 16 is optional and other types and numbers of adhering elements can be used. With the binder 16, the emission efficiency of the undoped quantum dots in layer 14(1) may improve because the binder 16 helps to slightly separate the undoped quantum dots. Additionally, the inclusion of the binder 16 may facilitate achieving a sufficiently smooth surface 17 on the layer of undoped quantum dots 14(1) so that an anti-reflective coating or other coating may be deposited directly on the layer of undoped quantum dots 14(1), although other types and numbers of coatings could be applied.

An anti-reflective coating 18(1) is located on the surface 17 of the layer 14(1) in this embodiment, although the anti-reflective coating 18(1) is optional and can be at other locations. The anti-reflective coating 18(1) is made of a material which is substantially transparent to the incoming light being absorbed and is substantially reflective at the emission wavelength of the undoped quantum dots in layer 14(1) to improve quantum efficiency of imaging sensor 12, although the anti-reflective coating 18(1) can comprise other numbers and types of layers and have other properties, such as acting as a filter to block unwanted wavelengths from reaching the layer of undoped quantum dots 14(1) or imaging sensor 12. The anti-reflective coating 18(1) is desirable because the emission from the layer of undoped quantum dots 14(1) is multi-directional so the anti-reflective coating 18(1) helps to redirect a portion of the emitted wavelength towards the imaging sensor 12 for detection improving quantum efficiency.

Referring to FIG. 2, another detection system 10(2) in accordance with other embodiments of the present invention is illustrated. The detection system 10(2) is the same in structure and operation as the detection system 10(1), expect as illustrated and described herein. Elements in detection system 10(2) which are like those in detection system 10(1) will have like reference numerals.

The layer 14(2) substantially contains two different sizes of undoped quantum dots, although other numbers of sizes of undoped quantum dots can be used in the layer 14(2), such as only one size or three or more sizes. In layer 14(2), the undoped quantum dots with the longer emission wavelength are placed adjacent a surface 19 of the layer 14(2) which faces towards the initial incoming light or other radiation being detected, although the undoped quantum dots of different sizes can be arranged in the layer 14(2) in other manners.

A window 22(1) is located adjacent to and spaced from the imaging sensor 12 by a spacer 20(1) to define a cavity 21, although the window 22(1) can be in other locations and other manners and devices for providing the spacing and other spacing arrangements can be used. The window 22(1) is made of a material which is substantially transparent to the wavelength or wavelengths of light or other radiation being detected, although the window can comprise other numbers and types of materials. The layer of undoped quantum dots 14(2) is applied to a surface 24(1) of the window 22(1) which is substantially smooth, although the layer of undoped quantum dots 14(2) can be at other locations, such as on an opposing surface 26(1) of window 22(1) from surface 24(1) by way of example only.

An anti-reflective coating 18(2) is located on the surface 26(1) of the window 22(1), although the anti-reflective coating 18(2) is optional and can be at other locations. The anti-reflective coating 18(2) is made of a material which is substantially transparent to the incoming light being absorbed and is substantially reflective at the emission wavelengths of the undoped quantum dots in layer 14(2) to improve quantum efficiency of imaging sensor 12, although the anti-reflective coating 18(2) can comprise other numbers and types of layers and have other properties, such as acting as a filter to block unwanted wavelengths from reaching the layer of undoped quantum dots 14(2) or imaging sensor 12. The anti-reflective coating 18(2) is desirable because the emission from the layer of undoped quantum dots 14(2) is multi-directional so the anti-reflective coating 18(2) helps to redirect a portion of the emitted wavelength towards the imaging sensor 12 for detection improving quantum efficiency of the detection system 10(2).

Referring to FIG. 3, another detection system 10(3) in accordance with other embodiments of the present invention is illustrated. The detection system 10(3) is the same in structure and operation as the detection system 10(1), expect as illustrated and described herein. Elements in detection system 10(3) which are like those in detection system 10(1) will have like reference numerals.

A window 22(2) is located adjacent to and spaced from the imaging sensor 12 by a spacer 20(2) which helps to define a cavity 23, although the window 22(2) can be in other locations and other manners and devices for providing the spacing and other spacing arrangements can be used. The window 22(2) is made of a material which is substantially transparent to the wavelength or wavelengths of light or other radiation being detected, although the window could be made of the other numbers and types of materials. The layer of undoped quantum dots 14(1) is applied to a surface 24(2) of the window 22(2) which is substantially smooth, although the layer of undoped quantum dots 14(2) can be at other locations, such as on an opposing surface 26(2) of window 22(2) from surface 24(2) by way of example only. Additionally, the layer of undoped quantum dots 14(1) could be optically coupled to the window 22(2) in other manners

A lens system 28 comprising a lens is supported by the spacer 20(2) and is positioned between and is spaced from the imaging sensor 12 and the layer of undoped quantum dots 14(1) on the window 22(2), although other types of lens or optical systems with other numbers and types of components in other configurations can be used, such as one or more mirrors. The lens system 28 directs the emission wavelength from the layer of undoped quantum dots 14(1), towards the imaging sensor 12. Although a spacer 20(2) is illustrated, other manners and types of supporting structures for providing the support and spacing can be used.

Referring to FIG. 4, another detection system 10(4) in accordance with other embodiments of the present invention is illustrated. The detection system 10(4) is the same in structure and operation as the detection system 10(1), expect as illustrated and described herein. Elements in detection system 10(4) which are like those in detection system 10(1) will have like reference numerals.

A spacer 20(3) is connected to and supports a fiber optic bundle 30 to position one output end 32 of the fiber optic bundle 30 adjacent an imaging sensor 12 and to define a cavity 27, although other manners and types of supporting structures for providing the support and other types of spacing can be used. Additionally, although a fiber optic bundle 30 is disclosed, other types and numbers of optical systems in other arrangements could be used. A layer of undoped quantum dots 14(2) is formed on an opposing end 34 of the fiber optic bundle 30, although the layer of undoped quantum dots 14(2) could be optically coupled to the end 34 of the fiber optic bundle 30 in other manners.

A method for detecting light with the detection system 10(1) in accordance with embodiments of the present invention will now be described with reference to FIG. 1. With this method, the detection system 10(1) is positioned towards a source of light to be captured, such as wavelengths ranging from infrared through ultraviolet. The incoming light passes through the anti-reflective coating 18(1) and is at least partially absorbed by the layer of undoped quantum dots 14(1).

The undoped quantum dots in layer 14(1) convert the absorbed light to an emission wavelength which is more suitable for detection by imaging sensor 12. The particular size of the undoped quantum dots in the layer 14(1) determines the emission wavelength and is selected to improve the quantum efficiency of the detection system 10(1). Since the layer 14(1) has one size of undoped quantum dots, the layer of 14(1) will emit one emission wavelength when the appropriate corresponding incoming light is absorbed, although layer 14(1) could have multiple sizes of undoped quantum dots to convert absorbed light into multiple emission wavelengths. Additionally, since the emissions from the undoped quantum dots in layer 14(1) are multi-directional, the anti-reflective coating 18(1) assists in redirecting the emission wavelength back towards the imaging sensor 12 to further enhance the quantum efficiency of the detection system 10(1).

A method for detecting light with the detection system 10(2) in accordance with embodiments of the present invention will now be described with reference to FIG. 2. The operation of the detection system 10(2) is the same as the detection system 10(1), expect as illustrated and described herein.

With this method, the detection system 10(2) is positioned towards a source of light to be captured, such as wavelengths ranging from infrared through ultraviolet. The incoming light passes through the anti-reflective coating 18(2) and through a window 22(1) and is at least partially absorbed by the layer of undoped quantum dots 14(2).

The undoped quantum dots in layer 14(2) convert the absorbed light to emission wavelengths which are more suitable for detection by imaging sensor 12. Since the layer 14(2) has two different sizes of undoped quantum dots, the layer of 14(2) will emit two different emission wavelengths when the appropriate corresponding incoming light is absorbed. Additionally, since the emissions from the undoped quantum dots in layer 14(2) are multi-directional, the anti-reflective coating 18(2) assists in redirecting the emissions wavelengths back towards the imaging sensor 12 to further enhance the quantum efficiency of the detection system 10(2).

A method for detecting light with the detection system 10(3) in accordance with embodiments of the present invention will now be described with reference to FIG. 3. The operation of the detection system 10(3) is the same as the detection system 10(1), expect as illustrated and described herein.

With this method, the detection system 10(3) is positioned towards a source of incoming light or other radiation to be captured, such as wavelengths ranging from infrared through ultraviolet. The incoming light passes through the window 22(2) and is at least partially absorbed by the layer of undoped quantum dots 14(1).

The undoped quantum dots in layer 14(1) convert the absorbed light to an emission wavelength which is more suitable for detection by imaging sensor 12. Since the layer 14(1) has one size of undoped quantum dots, the layer of 14(1) will emit one emission wavelength when the appropriate corresponding incoming light is absorbed. The lens system 28 focuses the emission wavelength from the undoped quantum dots in layer 14(1) on to the imaging sensor 12 to further enhance the quantum efficiency of the detection system 10(3).

In an alternative embodiment, the detection system 10(3) could be positioned so that the incoming light or radiation is absorbed by surface 25 of the layer of undoped quantum dots 14(2), although other arrangements can be used. In response to the absorbed light, the layer of undoped quantum dots 14(2) emits at the emission wavelengths towards the lens system 28 which operates as previously described.

A method for detecting light with the detection system 10(4) in accordance with embodiments of the present invention will now be described with reference to FIG. 4. The operation of the detection system 10(4) is the same as the detection system 10(1), expect as illustrated and described herein.

With this method, the detection system 10(4) is positioned towards incoming light or other radiation to be captured. The incoming light is at least partially absorbed by the layer of undoped quantum dots 14(2).

The undoped quantum dots in layer 14(2) convert the absorbed light to emission wavelengths which are more suitable for detection by imaging sensor 12. Since the layer 14(2) has two different sizes of undoped quantum dots, the layer of 14(2) will emit two different emission wavelengths into one end 34 of the fiber optic bundle 30. The emission wavelengths guided along the fiber optic bundle 30 are output from end 32 on to the imaging sensor 12 to further enhance the quantum efficiency of the detection system 10(4).

Accordingly, as described herein the present invention provides more effective and efficient methods and systems for detecting a broader spectrum of light or other radiation. The present invention is able to increase captured signal levels by several orders of magnitude. Additionally, the present invention is optically coupled to as opposed to being incorporated in or electrically coupled to the imaging sensor or other detector making the present invention substantially easier and less expensive to produce. Further, the present invention utilizes undoped quantum dots which are easier and less expensive to manufacture. Even further, the present invention is substantially more robust and will not suffer the degradation issues which have plagued prior detectors. The present invention also is able to provide a more rapid imaging response than previously could be achieved with prior art imaging sensors or other detectors.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations therefore, is not intended to limit the claimed processes to any order except as may be specified in the claims. Accordingly, the invention is limited only by the following claims and equivalents thereto.

What is claimed is:

1. A detection system comprising:
at least one imaging sensor that detects a band of wavelengths; and
at least one layer of undoped quantum dots optically coupled to the at least one imaging sensor, the at least one layer of undoped quantum dots absorbs at one or more wavelengths outside the band of wavelengths and outputs at least one emission wavelength in the band of wavelengths.

2. The system as set forth in claim 1 wherein the at least one layer of undoped quantum dots is on a surface of the at least one imaging sensor.

3. The system as set forth in claim 2 further comprising at least one binder in the at least one layer of undoped quantum dots.

4. The system as set forth in claim 3 further comprising at least one reflective coating layer on a surface of the at least one layer of undoped quantum dots with the at least one binder.

5. The system as set forth in claim 1 further comprising at least one window on a surface of the at least one layer of undoped quantum dots, wherein the window is substantially transparent to at least the bands of wavelengths and the one or more wavelengths outside the band of wavelengths.

6. The system as set forth in claim 5 further comprising at least one reflective coating layer on an opposing surface of the window from the surface with the at least one layer of undoped quantum dots.

7. The system as set forth in claim 5 further comprising at least one spacer which separates the at least one window on the surface of the at least one layer of undoped quantum dots from the at least one imaging sensor.

8. The system as set forth in claim 1 further comprising an optical system positioned to optically couple at least a portion of the at least one emission wavelength on at least a portion of the at least one imaging sensor.

9. The system as set forth in claim 8 wherein the optical system comprises at least one of one or more lens and one or more mirrors.

10. The system as set forth in claim 8 wherein the optical system comprises at least one fiber optic bundle.

11. The system as set forth in claim 1 wherein the at least one layer of undoped quantum dots has a substantially uniform thickness.

12. The system as set forth in claim 1 wherein the undoped quantum dots are all substantially the same size which output the same emission wavelength.

13. The system as set forth in claim 1 wherein the undoped quantum dots have at least two different sizes, each of the at least two different sizes output a different one of the emission wavelengths.

14. The system as set forth in claim 13 wherein the undoped quantum dots with one of the at least two different sizes which has the emission wavelength which is longer then the other one of the at least two different sizes is placed adjacent a side of the layer of undoped quantum dots which faces towards light to be detected.

15. The system as set forth in claim 1 wherein the band is above about 400 nm and the one or more wavelengths outside the band are below about 400 nm.

16. The system as set forth in claim 1 wherein the band is above about 1 micron and the one or more wavelengths outside the band are below about 1 micron.

17. A method for detecting light, the method comprising:
providing at least one imaging sensor that detects a band of wavelengths; and
optically coupling at least one layer of undoped quantum dots to the at least one imaging sensor, the at least one layer of undoped quantum dots absorbs at one or more wavelengths outside the band of wavelengths and outputs at least one emission wavelength in the band of wavelengths.

18. The method as set forth in claim 17 wherein the optically coupling further comprises placing the at least one layer of undoped quantum dots on a surface of the at least one imaging sensor.

19. The method as set forth in claim 18 further comprising adding at least one binder in with the at least one layer of undoped quantum dots.

20. The method as set forth in claim 19 further comprising providing at least one reflective coating layer on a surface of the at least one layer of undoped quantum dots with the at least one binder.

21. The method as set forth in claim 17 further comprising providing at least one window on a surface of the at least one layer of undoped quantum dots, wherein the window is substantially transparent to at least the bands of wavelengths and the one or more wavelengths outside the band of wavelengths.

22. The method as set forth in claim 21 further comprising providing at least one reflective coating layer on an opposing surface of the window from the surface with the at least one layer of undoped quantum dots.

23. The method as set forth in claim 21 further comprising providing at least one spacer which separates the at least one window on the surface of the at least one layer of undoped quantum dots from the at least one imaging sensor.

24. The method as set forth in claim 17 further comprising positioning an optical system to optically couple at the at least one emission wavelength on at least a portion of the at least one imaging sensor.

25. The method as set forth in claim 24 wherein the optical system comprises at least one of one or more lens and one or more mirrors.

26. The method as set forth in claim 24 wherein the optical system comprises at least one fiber optic bundle.

27. The method as set forth in claim 17 wherein the optically coupling at least one layer of undoped quantum dots further comprises forming the at least one layer of undoped quantum dots to have a substantially uniform thickness.

28. The method as set forth in claim 17 wherein the optically coupling at least one layer of undoped quantum dots further comprises selecting the undoped quantum dots to all be substantially the same size with a luminescence substantially tuned to match a peak sensitivity of the at least one imaging sensor.

29. The method as set forth in claim 17 wherein the undoped quantum dots have at least two different sizes, each of the at least two different sizes output a different one of the emission wavelengths.

30. The method as set forth in claim 29 wherein the undoped quantum dots with one of the at least two different sizes which has the emission wavelength which is longer then the other one of the at least two different sizes is placed adjacent a side of the layer of undoped quantum dots which faces towards light to be detected.

31. The method as set forth in claim 17 wherein the band is above about 400 nm and the one or more wavelengths outside the band of wavelengths are below about 400 nm.

32. The method as set forth in claim 17 wherein the band is above about 1 micron and the one or more wavelengths outside the band of wavelengths are below about 1 micron.
